(19) United States
(12) Patent Application Publication
(10) Pub. No.: US 2005/0149845 A1
(43) Pub. Date: Jul. 7, 2005

(54) Method of constructing QC-LDPC codes using qth-order power residue

(75) Inventors: Min-Ho Shin, Seoul (KR); Hong-Yeop Song, Seoul (KR); Seung-Bum Suh, Seoul (KR); Eoi-Young Choi, Seoul (KR)

Correspondence Address: DILWORTH & BARRESE, LLP, 333 EARLE OVINGTON BLVD., UNIONDALE, NY, 11553, US

(73) Assignees: SAMSUNG ELECTRONICS CO., LTD., GYEONGGI-DO (KR); YONSEI UNIVERSITY, SEOUL (KR)

(21) Appl. No.: 10/983,347

(22) Filed: Nov. 8, 2004

(30) Foreign Application Priority Data
Nov. 8, 2003 (KR) 78869/2003

(51) Int. Cl. H03M 13/00; G06F 11/00

(52) U.S. Cl. 714/801

(57) ABSTRACT

An LDPC encoding method in a digital communication system is provided, in which a parity-check matrix H having a plurality of circulant matrices as elements is first generated. A generation matrix G is generated using the parity-check matrix. Information bits are then encoded using the generation matrix G.

### PRIORITY

This application claims priority under 35 U.S.C. § 119 to an application entitled “Method of Constructing QC-LDPC Codes Using Qth-Order Power Residue” filed in the Korean Intellectual Property Office on Nov. 8, 2003 and assigned Serial No. 2003-78869, the contents of which are incorporated herein by reference.

### BACKGROUND OF THE INVENTION

1. Field of the Invention

The present invention relates generally to channel coding in a digital communication system, and in particular, to a method of constructing advanced LDPC (Low Density Parity Check) codes.

2. Description of the Related Art

LDPC codes have attracted a great deal of interest as a suitable coding scheme for a fourth generation (4G) mobile communication system due to superior performance and lower decoding complexity than turbo codes and parallel implementation.

An LDPC code is defined by a random sparse parity-check matrix H having a low density of Is. The matrix H is used to determine if a received signal has been decoded normally. If the product of the coded received signal and the matrix H is zero, it is determined that no errors have occurred. Therefore, the LDPC code is constructed by first designing a parity-check matrix that produces zero for every coded received signal by multiplication and then reversing a coding operation based on the matrix in an encoder of a transmitter.

The parity-check matrix H is designed such that the following constraints are satisfied: (1) each row has the same weight of k; (2) each column has the same weight of j (j is usually 3 or 4); and (3) any two columns have an overlap of at most 1. Here, a weight refers to the number of elements other than 0, that is, the number of elements having a value of 1, and the overlap between two columns refers to the inner product between rows. Therefore, the row weight and the column weight are very small relative to the code length.

The LDPC code can be decoded using an iterative decoding algorithm based on a sum-product algorithm on its factor graph. The use of the iterative decoding algorithm offers a lower complexity to an LDPC decoder than a turbo decoder and facilitates implementation of a parallel LDPC decoder.

Despite its excellent performance, however, the LDPC code has a distinctive shortcoming of very high code complexity relative to the turbo code. Basically being a block code, the LDPC code is formed by matrix multiplication and thus the code complexity is proportional to the square of a codeword length.

FIGS. 1A and 1B illustrate a conventional LDPC code constructing method and FIG. 1C illustrates a uniform check matrix for a coding rate ½-random LDPC code designed in the conventional LDPC code constructing method. In the check matrix, black dots indicate non-zero elements.

An LDPC coding routine derives a generation matrix through Gaussian elimination of a parity-check matrix and performs matrix multiplication. Because a low density of 1s is not maintained in the process of the LDPC coding, coding complexity considerably increases. While a coding algorithm for minimizing the volume of computation proportional to the square of a code length has been proposed along with other coding algorithms, which attempt to reduce the coding complexity, an encoder structure or a coding algorithm that remarkably reduces the coding complexity is yet to be developed. Accordingly, there is a pressing need for an LDPC encoder that reduces the coding complexity and operates in a coding scheme suitable for the next-generation mobile communication system.

### SUMMARY OF THE INVENTION

Therefore, the present invention has been designed to substantially solve at least the above problems and/or disadvantages and to provide at least the advantages below. Accordingly, an object of the present invention is to provide an encoding method for efficiently generating an LDPC code.

Another object of the present invention is to provide an encoding method for greatly reducing coding complexity and offering an optimum coding gain.

A further object of the present invention is to provide an encoding method for reducing a small cycle length in designing a parity-check matrix to increase independence in iterative decoding and thus, increase performance.

Still another object of the present invention is to provide an encoding method for reducing a coding time delay through parallel coding of blocks.

Yet another object of the present invention is to provide an encoding method for generating a codeword with a variable coding rate and a variable length using a single hardware structure.

The above and other objects are achieved by providing an LDPC encoding method in a digital communication system. In the LDPC encoding method, a parity-check matrix H having a plurality of circulant matrices as elements is first generated. A generation matrix G is generated using the parity-check matrix. Next, information bits are encoded using the generation matrix G.

### BRIEF DESCRIPTION OF THE DRAWINGS

The above and other objects, features, and advantages of the present invention will become more apparent from the following detailed description when taken in conjunction with the accompanying drawings in which:

FIGS. 1A and 1B illustrate conventional LDPC code structures with coding rates of ½ and ⅓, respectively;

FIG. 1C illustrates an example of a uniform check matrix for a random LDPC code designed in a conventional LDPC code constructing method illustrated in FIGS. 1A and 1B;

FIG. 2 is a flowchart illustrating an encoding method according to a preferred embodiment of the present invention;

FIG. 3A illustrates a parity-check matrix for an LDPC code designed in the encoding method according to a preferred embodiment of the present invention;

FIG. 3B illustrates a systematic check matrix derived through systematic modification to the parity-check matrix illustrated in FIG. 3A;

FIG. 4 illustrates an encoder that performs the encoding method according to a preferred embodiment of the present invention;

FIG. 5 illustrates an encoder that can operate for various coding rates and various code lengths; and

FIG. 6 is a graph comparing in terms of performance a conventional random LDPC code with an LDPC code generated according to a preferred embodiment of the present invention.

### DETAILED DESCRIPTION OF THE PREFERRED EMBODIMENT

Preferred embodiments of the present invention will be described in detail herein below with reference to the accompanying drawings. In the following description, well-known functions or constructions are not described in detail because they would obscure the invention in unnecessary detail.

The present invention pertains to designing an encoder for generating an error correction code, i.e., an LDPC code, in a digital communication system. The LDPC encoder is designed such that similar performance as that of a conventional encoder can be achieved by efficiently performing a coding operation using shift registers, which is traditionally done by matrix computation. The LDPC encoder creates a QC (Quasi Cyclic)-LDPC code having m×n circulant matrix blocks. A computation between circulant matrices in the QC-LDPC code has an algebraic property that it can be replaced with an equivalent polynomial computation. Therefore, the LDPC encoder is easy to realize.

The present invention provides a method of equivalently describing each circulant matrix block by polynomials using qth-order residues, as a uniform LDPC code having the above configuration. The inventive LDPC encoding method easily generates an LDPC code with a variable coding rate and a variable length through puncturing or shortening and can be efficiently applied as a channel coding scheme for the future-generation communication system or a storage device, which requires high-speed signal transmission.

In accordance with the present invention, a check matrix H for an LDPC code has m×n blocks, each being a circulant matrix. The circulant matrix is of a pxp size, where p is a prime number. The check matrix H is generalized in Equation (1).

$$H = [ \begin{matrix}{H}_{11} & {H}_{12} & ⋯ & {H}_{1 m} & ⋯ & {H}_{1 n} \\ {H}_{21} & {H}_{22} & ⋯ & {H}_{2 m} & ⋯ & {H}_{2 n} \\ ⋮ & ⋮ & ⋰ & ⋮ & ⋮ & ⋮ \\ {H}_{m1} & {H}_{m2} & ⋯ & {H}_{mm} & ⋯ & {H}_{mn}\end{matrix} ] ⇔ \\ H ( x ) = [ \begin{matrix}{h}_{11} ( x ) & {h}_{12} ( x ) & ⋯ & {h}_{1 m} ( x ) & ⋯ & {h}_{1 n} ( x ) \\ {h}_{21} ( x ) & {h}_{22} ( x ) & ⋯ & {h}_{2 m} ( x ) & ⋯ & {h}_{2 n} ( x ) \\ ⋮ & ⋮ & ⋰ & ⋮ & ⋮ & ⋮ \\ {h}_{m1} ( x ) & {h}_{m2} ( x ) & ⋯ & {h}_{mm} ( x ) & ⋯ & {h}_{mn} ( x )\end{matrix} ] \qquad ( 1 )$$

Each circulant matrix Hᵢⱼ can be equivalently described by Equation (1a):

$${h}_{ij} ( x ) = {\sum }_{k = 0}^{p - 1} {( {H}_{ij} )}_{0 k} {x}^{k} \qquad ( 1 a )$$

and computation between circulant matrices is replaced by polynomial computation.

This LDPC code comprised of circulant matrices is quasi cyclic. That is, one LDPC codeword is changed to another LDPC codeword by an n-bit shift. Each circulant matrix in the LDPC code can be expressed as a matrix of polynomials using qth-order power residue classes according to Equation (2):

$$H ( x ) := [ \begin{matrix}( 1 , - 1 ) & ( α , - α ) & ⋯ & ( {α}^{n - 1} , - {α}^{n - 1} ) \\ ( {α}^{n} , - {α}^{n} ) & ( {α}^{n + 1} , - {α}^{n + 1} ) & ⋯ & ( {α}^{2 n - 1} , - {α}^{2 n - 1} ) \\ ⋮ & ⋮ & ⋰ & ⋮ \\ ( {α}^{( m - 1 ) n} , - {α}^{( m - 1 ) n} ) & ( {α}^{( m - 1 ) n + 1} , - {α}^{( m - 1 ) n + 1} ) & ⋯ & ( {α}^{mn - 1} , - {α}^{mn - 1} )\end{matrix} ] \qquad ( 2 )$$

where (a, −a) is set forth in Equation (2a):
(a, −a):=x^{a}+X^{p-a} (2a)

The LDPC code is uniform according to the present invention. Because the uniform LDPC code optimally performs for a column weight of 3, the LDPC code is configured to have a column weight of 3 in Equation (3).

$$H ( x ) = [ \begin{matrix}{h}_{11} ( x ) & 0 & 0 & ⋯ & {h}_{1 m} ( x ) & {h}_{1 , m + 1} ( x ) & ⋯ \\ {h}_{21} ( x ) & {h}_{22} ( x ) & 0 & ⋯ & 0 & {h}_{2 , m + 1} ( x ) & ⋯ \\ 0 & {h}_{32} ( x ) & {h}_{33} ( x ) & ⋯ & 0 & 0 & ⋯ \\ ⋮ & ⋮ & ⋮ & ⋰ & ⋮ & ⋮ & ⋯ \\ 0 & 0 & 0 & ⋯ & {h}_{mm} ( x ) & 0 & ⋯\end{matrix} ] \qquad ( 3 )$$

Here, the number of polynomial terms is set to 2 or less, which implies that the number of Is in the first row in each circulant matrix block is 2 or less.

In Equation (3), the weight of polynomials h_{i,kj+i}(x) (1≦i≦m, 0≦k) is 2 and the weight of the other polynomials is 1.

The above LDPC code has a parity-check matrix H, which is modified to a systematic matrix H′.

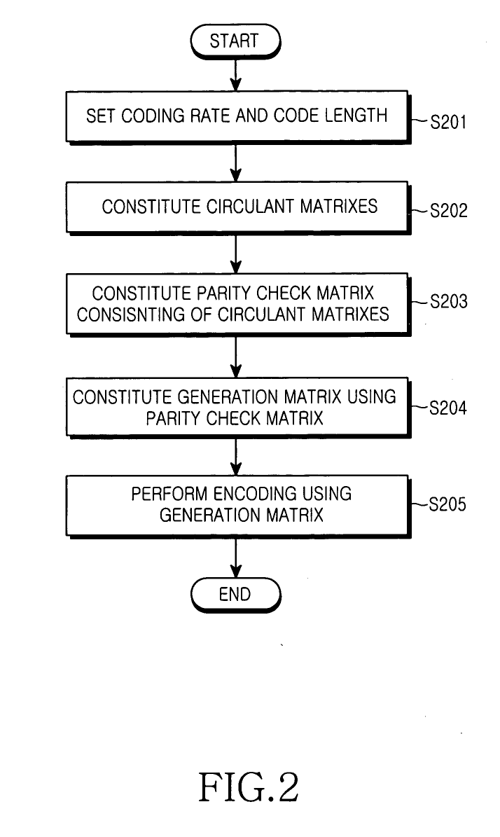

FIG. 2 is a flowchart illustrating the encoding method according to a preferred embodiment of the present invention. Referring to FIG. 2, a coding rate and a code length are set for an LDPC code in step S201. The coding rate is determined to be (n-m)/n, according to the number of row blocks m and the number of column blocks n of the parity-check matrix H. The code length is a multiple np of the prime number p being the size of a circulant matrix block. The parity-check matrix H includes m rows and n columns, each being a circulant matrix.

In step S202, circulant matrices are formed. Each circulant matrix is an equivalent polynomial matrix derived using a (p−1)/2th-order power residue (or a (p−1)/2-th power residue), that is, (1, −1), and non-residues. If the circulant matrix is an m×n matrix, the polynomial of each row/column block is determined from the power residue by Equation (2). Here, α is a primitive root of a finite field GF(p). That is, a polynomial is formed by sequentially arranging a power residue and a non-residue. (α, −α) is defined as a polynomial x^{a}+x^{p-a}.

After forming the circulant matrices, the parity-check matrix H with a column weight of 3 is formed by selecting a weight distribution for each circulant matrix according to Equation (3) in step S203. The polynomial weight is 0, 1, or 2 in each circulant matrix, and the polynomials determined by Equation (2) are punctured according to a new polynomial weight.

When the uniform parity-check matrix H having the column weight of 3 is formed, a systematic encoder is configured through a generation matrix in step S204. The left square matrix in the parity-check matrix H has an inverse matrix all the time. Thus, H can be changed to H′=[I |P] by row computation. The systematic matrix H′ is expressed in Equation (4).

$${H}^{′} = [ I \vert P ] ⟺ {H}^{′} ( x ) = [ \begin{matrix}1 & 0 & ⋯ & 0 & {p}_{11} ( x ) & {p}_{12} ( x ) & ⋯ & {p}_{1 k} ( x ) \\ 0 & 1 & ⋯ & 0 & {p}_{21} ( x ) & {p}_{22} ( x ) & ⋯ & {p}_{2 k} ( x ) \\ ⋮ & ⋮ & ⋰ & ⋮ & ⋮ & ⋮ & ⋰ & ⋮ \\ 0 & 0 & ⋯ & 1 & {p}_{m1} ( x ) & {p}_{m2} ( x ) & ⋯ & {p}_{mk} ( x )\end{matrix} ] \qquad ( 4 )$$

Using Equation (4), a systematic encoder can be designed to have a generation matrix G=[P^{T}|I] and encoding is performed by polynomial multiplication instead of matrix multiplication. Here, k=n-m, which indicates the size of an information symbol block.

In step S205, encoding is performed in the thus-constituted systematic encoder. A total information vector length is pk and encoding is performed on the basis of k blocks, each having p information vectors.

Information vectors m=[m₁, m₂ . . . , mₖ] can be represented as m(x)=[m₁(x), m₂(x) . . . , mₖ(x)], which is equivalent to a polynomial modular x^{p}−1 on a finite field GF(2). Therefore, a codeword c=mG can be achieved as shown in Equation (4a):

$$c = mG \\ = [ {mP}^{T} \vert m ] ⇔ c ( x ) \\ = [ {p}_{1} ( x ) , {p}_{2} ( x ) , … , {p}_{m} ( x ) \vert m ( x ) ] , \\ {p}_{i} ( x ) = {\sum }_{j = 1}^{k} {m}_{j} ( x ) {p}_{ij} ( x ) \qquad ( 4 a )$$

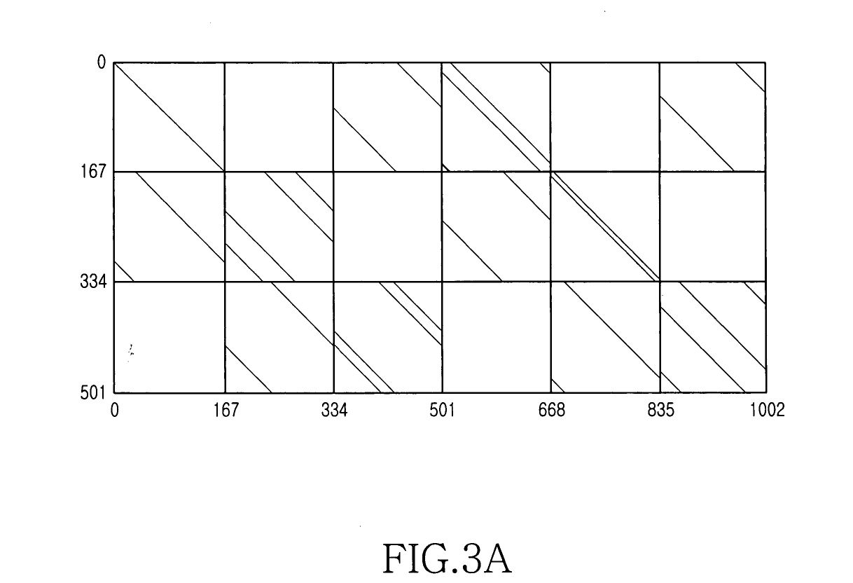

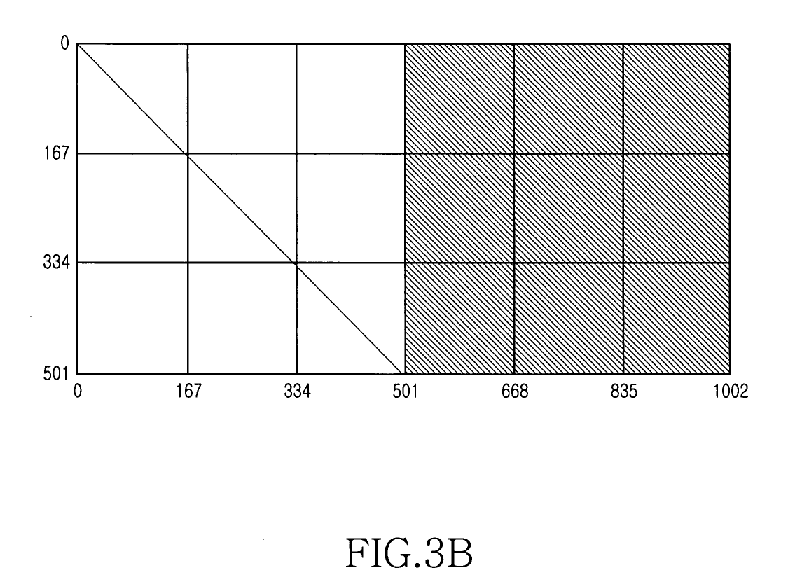

FIG. 3A schematically illustrates the parity-check matrix H generated by the encoding method according to a preferred embodiment of the present invention. Referring to FIG. 3A, the parity-check matrix H for a QC-LDPC code comprises a plurality of circulant matrices. Each slant line denotes the positions of elements being Is and the remaining area other than the slant lines have elements being 0s. The parity-check matrix has a length of 1002. It includes 3 row blocks and 6 column blocks. A coding rate is ½, the prime number used is 167, and a selected primitive root is 123.

FIG. 3B illustrates a systematic matrix H′ derived from the matrix H as illustrated in FIG. 3A. Because the left square matrix in the parity-check matrix H has an inverse matrix all the time, H is changed to H′=[I|P] by row computation. As illustrated in FIG. 3B, the systematic matrix H′ has a unit matrix at its left half and a parity matrix P at its right half.

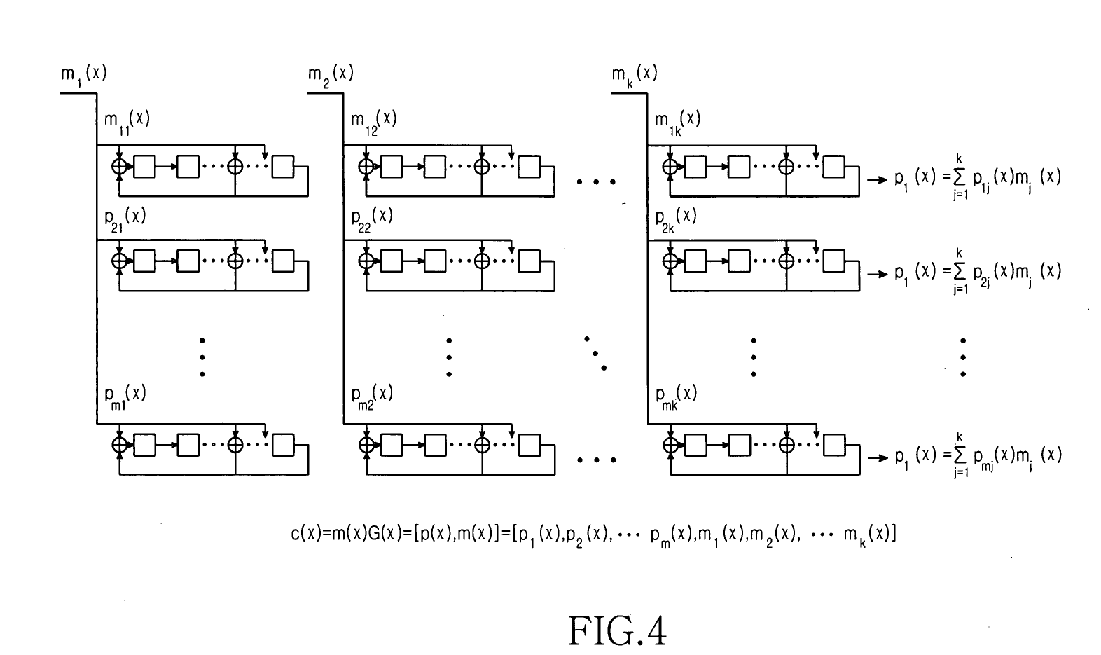

FIG. 4 illustrates an encoding operation by parallel processing using shift registers according to a preferred embodiment of the present invention. Referring to FIG. 4, encoding is performed using shift registers by polynomial multiplication instead of matrix multiplication. More specifically, information bits to be transmitted can be expressed as a polynomial m(x) and a codeword polynomial c(x) is derived by multiplying the information bit polynomial m(x) by a generation matrix polynomial G(x) having a check bit polynomial p(x) as an element. Therefore, c(x) is determined as shown below in Equation (5).
c(x)=m(x)G(x)=[p(x), m(x)]=[p₁(x, P₂(x), . . . , pₘ(x), m₁(x), . . . , m₂ (x), . . . , mₖ(x)] (5)

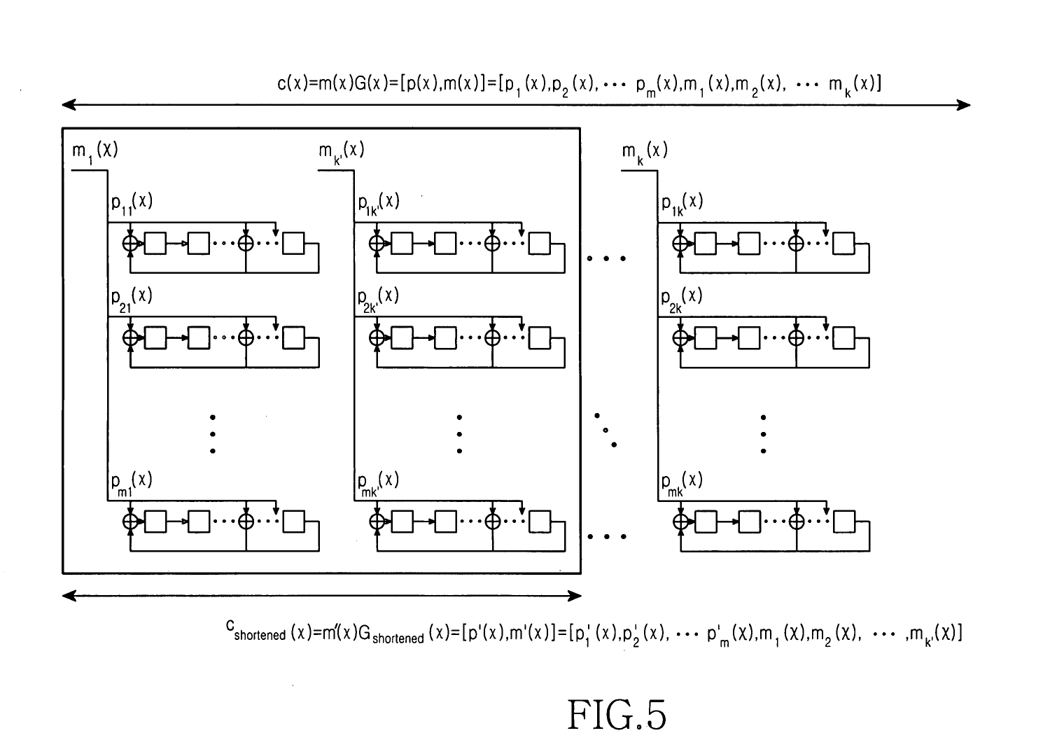

FIG. 5 illustrates an LDPC encoder for generating a code with a code length of np and a coding rate of k/n and its shortened code with a coding rate of k′/p. A shortened codeword c_{shortened}(x) is generated by multiplying an information bit polynomial m′(x) by a shortened generation matrix polynomial G_{shortened}(x), as shown below in Equation (6).
c_{shortened}(x)=m′(x)G_{shortened}(x)=[p′(x), m′(x)]=[p₁′(x), p₂′(x), . . . , pₘ′(x), m₁(x), m₂(x), . . . , mₖ, (x)] (6)

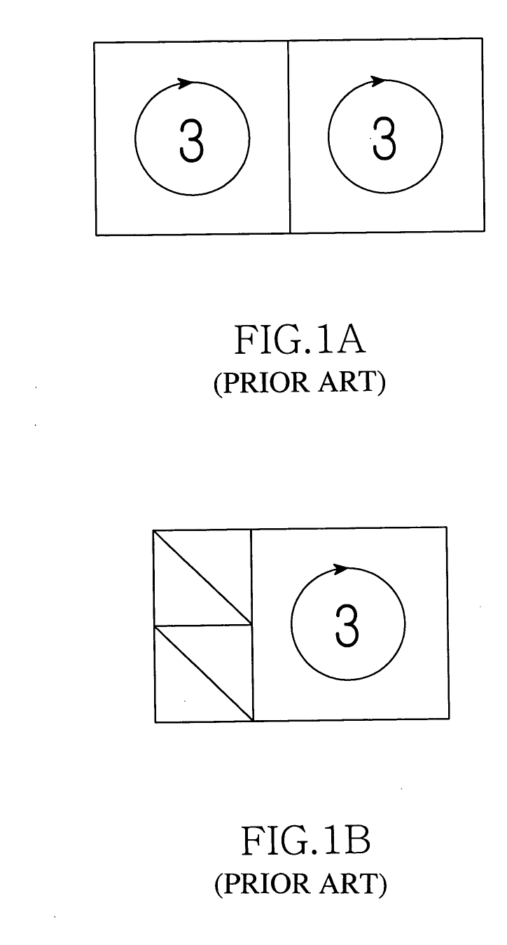

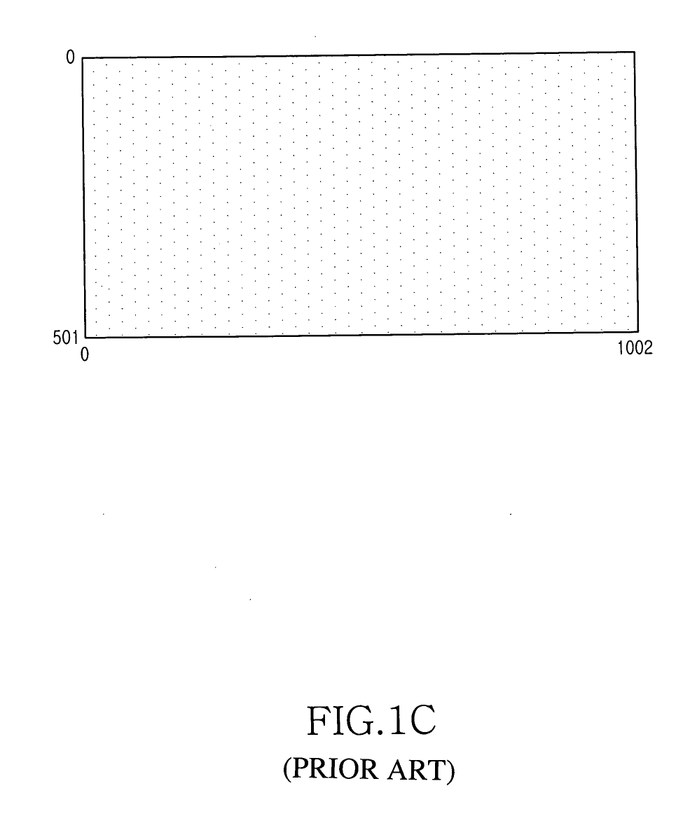

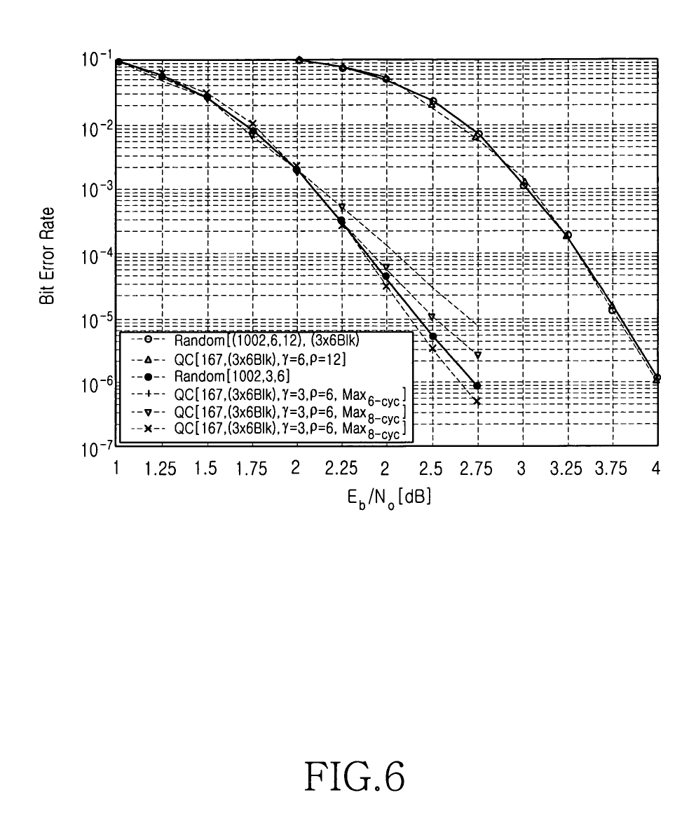

FIG. 6 is a graph comparing in terms of performance a conventional random LDPC code with an LDPC code generated according to a preferred embodiment of the present invention. To analyze LDPC code performance, a simulation was performed using a sum-product algorithm with a maximum iterative decoding number limited to 80 in a typical AWGN (Additive White Gaussian Noise) channel environment. The random LDPC encoding method having a code length of 1002 and a coding rate of ½ as illustrated in FIG. 1 was used as a comparative example. In the inventive LDPC encoding method, a cycle 4-free and cycle 6-free check matrix can be formed by appropriately selecting the primitive root α. As noted from FIG. 6, the QC-LDPC code of the present invention demonstrates the same decoding performance as that of the conventional random LDPC code, even though it has a lower coding complexity.

As described above, in accordance with the encoding method of the present invention, a generation matrix is formed in the form of a block matrix having circulant matrices as its elements. Matrix multiplication between circulant matrices can be performed by an equivalent polynomial multiplication. As a result, encoding can be efficiently performed using shift registers.

Additionally, a short cycle is remarkably reduced in forming a parity-check matrix, thereby increasing independency in iterative decoding and thus improving performance.

Also, because encoding is performed through block-by-block parallel processing, a coding time delay can be shortened.

Further, codewords with various coding rates and various code lengths can be generated by use of a single hardware structure.

Accordingly, an LDPC code generated according to the present invention offers almost a comparable decoding performance as the conventional random LDPC code, but is improved in that it has a lower coding complexity.

While the present invention has been shown and described with reference to certain preferred embodiments thereof, it will be understood by those skilled in the art that various changes in form and details may be made therein without departing from the spirit and scope of the present invention as defined by the appended claims.

1. A low density parity check (LDPC) encoding method in which parity bits are added to information bits, comprising the steps of:
generating a parity-check matrix H including a plurality of circulant matrices as elements;
generating a generation matrix G using the parity-check matrix; and
encoding the information bits using the generation matrix G.

2. The LDPC encoding method of claim 1, wherein the parity-check matrix H is an m×n matrix including m circulant matrix rows and n circulant matrix columns.

3. The LDPC encoding method of claim 2, wherein m is 3 and n is 6.

4. The LDPC encoding method of claim 1, wherein each of the circulant matrices is a p×p matrix.

5. The LDPC encoding method of claim 4, wherein the parity-check matrix generating step comprises setting a coding rate and a code length for an output LDPC code.

6. The LDPC encoding method of claim 5, wherein the coding rate is (n-m)/n where n is a number of columns of the parity-check matrix and m is a number of rows of the parity-check matrix.

7. The LDPC encoding method of claim 5, wherein the code length is p×n, where p is a length of the circulant matrix and n is a length of the parity-check matrix.

8. The LDPC encoding method of claim 5, wherein the parity-check matrix generating step comprises forming the parity-check matrix using matrices equivalent to polynomials derived from (1, −1) being a (p−1)/2th-order power residue class and a non-residue.

9. The LDPC encoding method of claim 8, wherein the parity-check matrix generating step comprises reconstructing the circulant matrices such that a column weight of the parity-check matrix is 3.

10. The LDPC encoding method of claim 9, wherein the generation matrix generating step comprises forming a modified check matrix H′ by row computation of the parity-check matrix.

11. The LDPC encoding method of claim 10, wherein the modified check matrix H′ is in a systematic form of H′=[I|P], where I is a unit matrix.

12. The LDPC encoding method of claim 11, wherein the generation matrix generating step comprises forming the generation matrix G from the modified check matrix H′.

13. The LDPC encoding method of claim 12, wherein the generation matrix G is in the systematic form of G=[P^{T}|I], where P^{T} is a transformed matrix of P.

14. The LDPC encoding method of claim 12, wherein the information bit encoding step comprises generating a codeword c by multiplying the information bits by the generation matrix G.

15. The LDPC encoding method of claim 14, wherein the codeword c is generated by polynomial multiplication instead of matrix multiplication.
